(19) United States
(12) Patent Application Publication
(10) Pub. No.: US 2014/0308767 A1
(43) Pub. Date: Oct. 16, 2014

(54) METHOD FOR MANUFACTURING LIGHT EMITTING DIODE PACKAGES

(71) Applicant: ADVANCED OPTOELECTRONIC TECHNOLOGY, INC., Hsinchu Hsien 303 (TW)

(72) Inventors: HOU-TE LIN, Hsinchu (TW); CHAO-HSIUNG CHANG, Hsinchu (TW); PIN-CHUAN CHEN, Hsinchu (TW); LUNG-HSIN CHEN, Hsinchu (TW)

(73) Assignee: ADVANCED OPTOELECTRONIC TECHNOLOGY, INC., Hsinchu Hsien 303 (TW)

(21) Appl. No.: 14/221,219

(22) Filed: Mar. 20, 2014

(30) Foreign Application Priority Data
Apr. 10, 2013 (CN) 2013101216761

(51) Int. Cl. H01L 33/62

(52) U.S. Cl. CPC H01L 33/62
USPC 438/27

(57) ABSTRACT

A method for manufacturing LED packages includes steps: providing a lead frame including many pairs of first and second electrodes and first and second tie bars respectively located at opposite ends of each pair of the electrodes, the first and second electrodes each including a main body and an extension electrode protruding outwardly from the main body; forming many molded bodies to engage with the first and second electrodes, the first and second main bodies being embedded into the molded bodies, and the first and second extension electrodes being exposed from a periphery of the molded body; removing the first and second tie bars from the lead frame; disposing LED dies in corresponding receiving cavities defined by the molded bodies; and cutting the molded bodies and the lead frame to obtain a plurality of individual LED packages.

### 1. TECHNICAL FIELD

The present disclosure relates to a method for manufacturing light emitting diode (LED) packages, and particularly to a method for manufacturing LED packages wherein a molded body of each LED package has a firm connection with a lead frame thereof whereby the LED package can have a good sealing performance for an LED die thereof

### 2. DESCRIPTION OF RELATED ART

LEDs are solid state light emitting devices formed of semiconductors, which are more stable and reliable than other conventional light sources such as incandescent bulbs. Thus, LEDs are widely used in various fields such as numeral/character displaying elements, signal lights, light sources for lighting and display devices.

A typical method for manufacturing LED package usually includes the following steps: providing a lead frame with electrical structures (i.e., electrodes) formed thereon; forming a molded body having a plurality of reflecting cups engaging with the lead frame, each reflecting cup defining a receiving cavity therein; disposing a plurality of LED dies in the receiving cavities and electrically connecting each LED die to a pair of electrical structures formed by the lead frame and exposed at the bottom of the corresponding receiving cavity by gold wires; forming an encapsulating layer in each receiving cavity to encapsulate the LED die therein; and cutting the molded body and the lead frame to obtain a plurality of individual LED packages. However, the LED packages manufactured by the method have a low bonding force between the molded body and the lead frame, whereby the molded body and the lead frame having the electrical structures are easily to separate from each other, resulting in a poor sealing performance for the LED dies of the LED packages.

What is needed, therefore, is a method for manufacturing light emitting diode packages which can overcome the above-mentioned limitations.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a flow chart of a method for manufacturing light emitting diode packages in accordance with the present disclosure.

FIG. 2 is a top plan view of a lead frame for forming the light emitting diode packages in accordance with a first embodiment of the present disclosure, wherein the lead frame is prepared in accordance with a first step of the method shown in FIG. 1.

FIG. 3 is an enlarged view of part III of the lead frame of FIG. 2, and shows a pair of electrodes thereof, together with two tie bars respectively located at opposite outer ends of the pair of electrodes.

FIG. 4 is similar to FIG. 3, but viewed from an inverted aspect.

FIG. 5 is a cross-sectional view of the lead frame of FIG. 3, taken along line V-V thereof.

FIG. 6 is a cross-sectional view of the lead frame of FIG. 4, taken along line VI-VI thereof

FIG. 7 is a cross-sectional view of the lead frame of FIG. 4, taken along line VII-VII thereof

FIG. 8 is a schematic, cross-sectional view of a part of the lead frame of FIG. 2, together with a mold accommodating the part of the lead frame therein, wherein only a pair of electrodes of the lead frame is shown.

FIG. 9 is similar to FIG. 8, but viewed from a bottom of the part of the lead frame shown in FIG. 8, wherein a female mold (i.e., a lower half) of the mold is removed for clarity.

FIG. 10 is a top plan view of a semi-finished product for forming the light emitting diode packages, wherein the semi-finished product is obtained by a second step of the method shown in FIG. 1.

FIG. 11 is an enlarged view of part XI of the semi-finished product of FIG. 10.

FIG. 12 is a cross-sectional view of the semi-finished product of FIG. 11, taken along line XII-XII thereof

FIG. 13 is similar to FIG. 11, but viewed from an inverted aspect.

FIG. 14 is a top view of a light emitting diode package obtained by the method shown in FIG. 1.

FIG. 15 is a cross-sectional view of the light emitting diode package of FIG. 14, taken along line XV-XV thereof

FIG. 16 is similar to FIG. 14, but viewed from an inverted aspect.

FIG. 17 is a top plan view of part of a lead frame for forming the light emitting diode packages in accordance with a second embodiment of the present disclosure, wherein the lead frame is prepared in accordance with a first step of the method shown in FIG. 1, and wherein a pair of electrodes with two tie bars respectively located at opposite outer ends thereof are shown.

FIG. 18 is similar to FIG. 17, but viewed from an inverted aspect.

FIG. 19 is a cross-sectional view of the lead frame of FIG. 17, taken along line XIX-XIX thereof.

### DETAILED DESCRIPTION

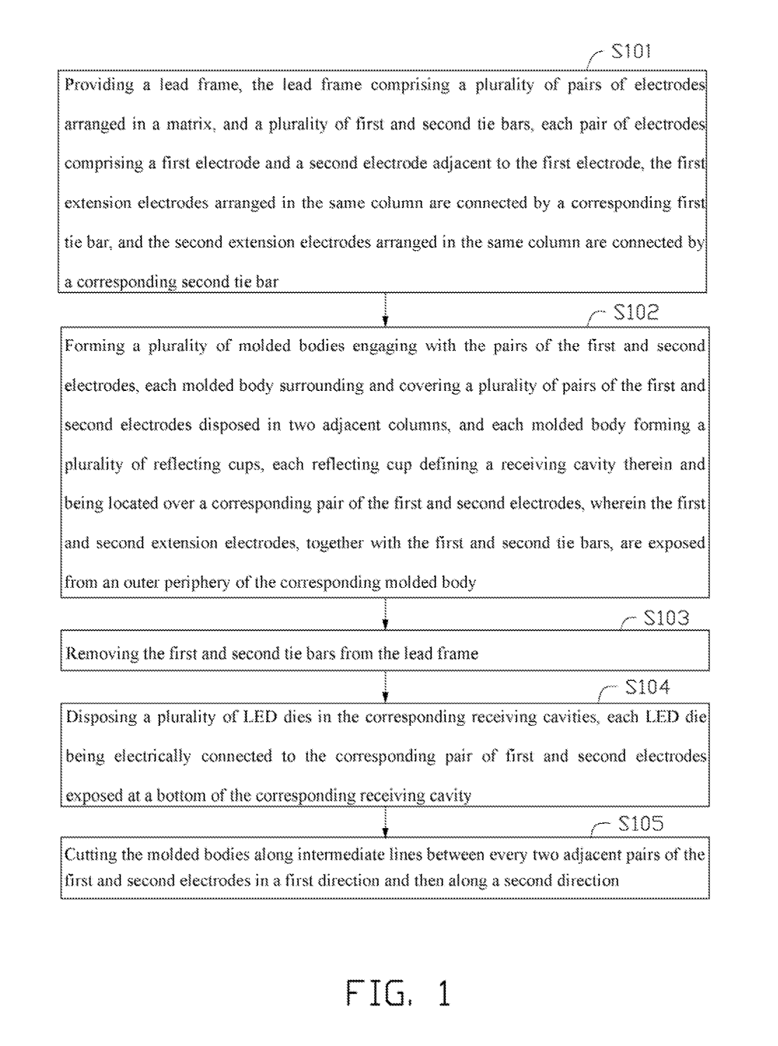

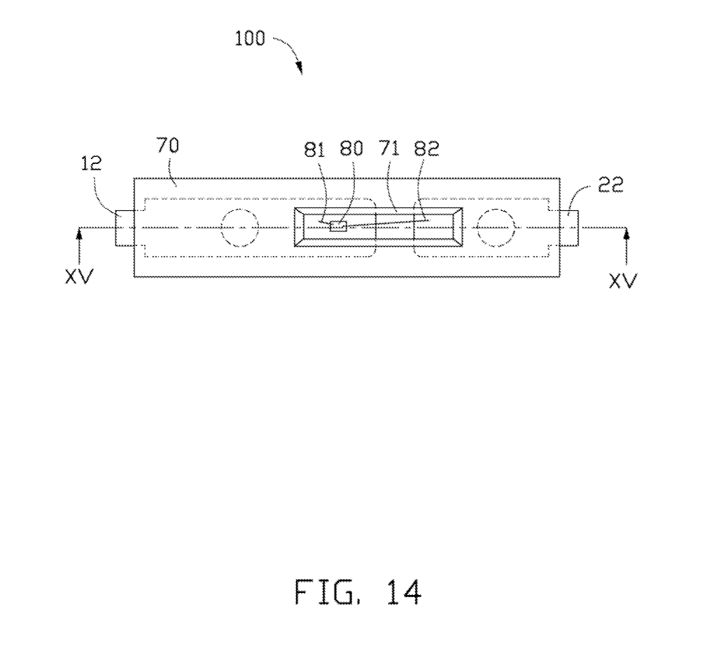

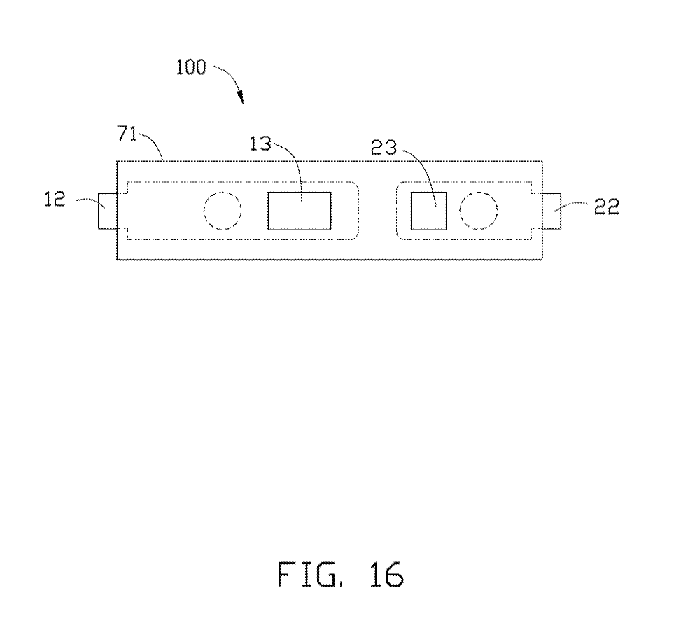

Referring to FIG. 1, a method for manufacturing light emitting diode (LED) packages 100 (see FIGS. 14-16 which show one LED package 100) in accordance with the present disclosure is shown. The method includes the following steps:

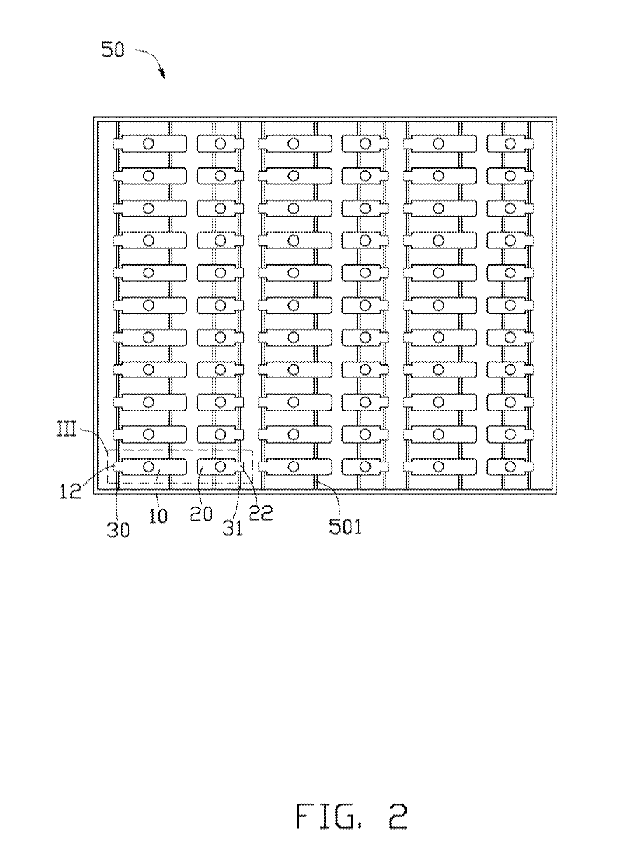

In step S101 (also referring to FIG. 2), a lead frame 50 is provided. The lead frame 50 includes a plurality of pairs of electrodes arranged in a matrix, and a plurality of first and second tie bars 30, 31. Each pair of electrodes includes a first electrode 10 and a second electrode 20 adjacent to the first electrode 10. The first electrodes 10 arranged in a column are connected together by a corresponding first tie bar 30, and the second electrodes 20 arranged in a column are connected together by a corresponding second tie bar 31.

The lead frame 50 has a plurality of metal wires 501 extending between two opposite sides (i.e., the top side and the bottom side as viewed from FIG. 2) thereof. The first and second electrodes 10, 20 are firmly fixed onto the lead frame 50 by the metal wires 501. In the present embodiment, there are three columns of first electrodes 10 and three columns of second electrodes 20. The three columns of first electrodes 10 and the three columns of second electrodes 20 are arranged alternately along a predetermined direction (i.e., the left-to-right direction as viewed from FIG. 2) of the lead frame 50. Because the plurality of pairs of electrodes, i.e., the first and second electrodes 10, 20, have structures similar to each other, the following description and the accompanying drawings mainly illustrate one pair of the first and second electrodes 10, 20.

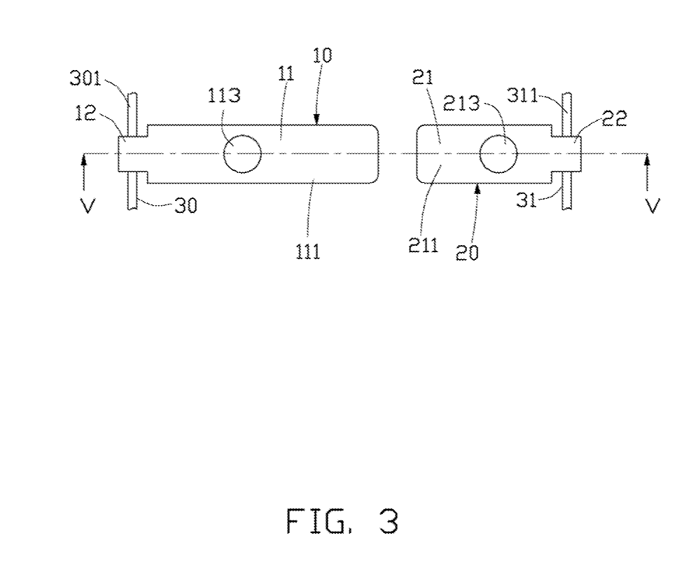

Referring also to FIGS. 3-5, the first electrode 10 includes an elongated first main body 11 having a top surface 111 and a bottom surface 112 at opposite sides thereof, a first extension electrode 12 protruding laterally from a left end of the first main body 11 and far away from the second electrode 20 which is in the same pair with the first electrode 10, and a first supporting branch 13 protruding downwardly from the bottom surface 112 of the first main body 11 and close to the second electrode 20 which is in the same pair with the first electrode 10.

The second electrode 20 includes an elongated second main body 21 having a top surface 211 and a bottom surface 212 at opposite sides thereof, a second extension electrode 22 protruding laterally from a right end of the second main body 21 and far away from the first electrode 10 which is in the same pair with the second electrode 20, and a second supporting branch 23 protruding downwardly from the bottom surface 212 of the second main body 21 and close to the first electrode 10 which is in the same pair with the second electrode 20. In the present embodiment, the first main body 11 and the second main body 21 in the same pair are arranged, as depicted in FIG. 3, in a line extending along the left-to-right direction. Widths of the first and second extension electrodes 12, 22 are smaller than that of the corresponding first and second main bodies 11, 21, respectively.

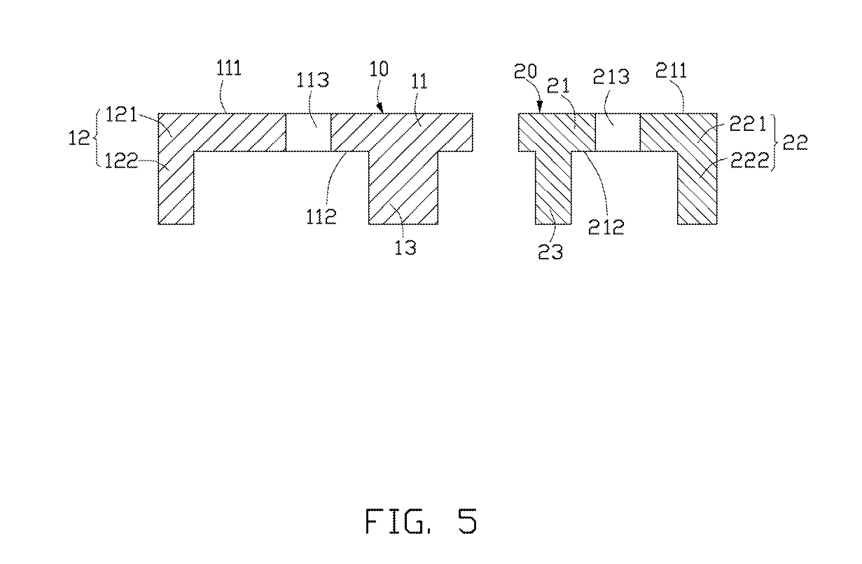

As shown in FIG. 5, the first and second extension electrodes 12, 22 each have an inverted L-shaped configuration. The first extension electrode 12 includes a first connecting portion 121 extending horizontally and outwardly from the left end of the first main body 11, and a first extension portion 122 extending downwardly from a left end of the first connecting portion 121 and substantially perpendicular to the first connecting portion 121. The second extension electrode 22 includes a second connecting portion 221 extending horizontally and outwardly from the right end of the second main body 21, and a second extension portion 222 extending downwardly from a right end of the second connecting portion 221 and substantially perpendicular to the second connecting portion 221. Tops of the first and second extension electrodes 12, 22 are coplanar with the top surfaces 111, 211 of the first and second main bodies 11, 21. Bottoms of the first and second extension electrodes 12, 22 are coplanar with bottoms of the first and second supporting branches 13, 23.

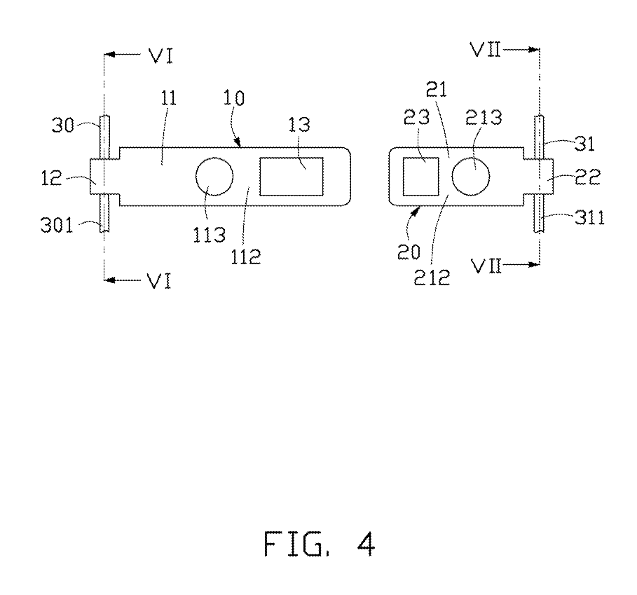

As shown in FIGS. 3 and 4, the first tie bar 30, for each first electrode 10, includes two spaced first connecting sections 301 each extending between two adjacent first electrodes 10 arranged in the same column. Each first connecting section 301 is spaced from the corresponding first main body 11 by a short distance. The second tie bar 31, for each second electrode 20, includes two spaced second connecting sections 311 each extending between two adjacent second electrodes 20 arranged in the same column. Each second connecting section 311 is spaced from the corresponding second main body 21 by a short distance.

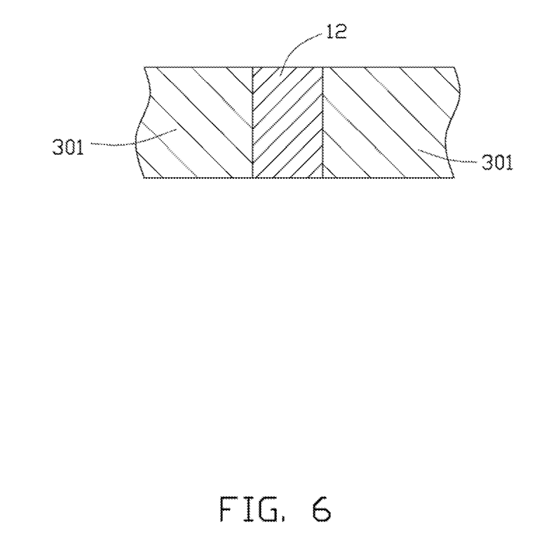

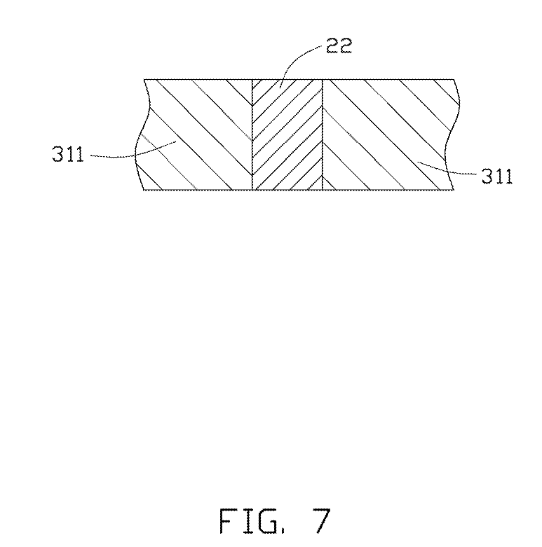

Referring to FIGS. 6 and 7, a height of the first connecting section 301 is equal to that of the first extension electrode 12. A height of the second connecting section 311 is equal to that of the second extension electrode 22. Tops of the first and second extension electrodes 12, 22 are coplanar with tops of the first and second connecting sections 301, 311, respectively. Bottoms of the first and second extension electrodes 12, 22 are coplanar with bottoms of the first and second connecting sections 301, 311, respectively.

Referring to FIGS. 4-5 again, the first and second supporting branches 13, 23 are rectangular prisms, respectively. A width of the first supporting branch 13 is smaller than that of the first main body 11, and a width of the second supporting branch 23 is smaller than that of the second main body 21. The first supporting branch 13 is near the right end of the first main body 11 and adjacent to the second electrode 20 which is in the same pair with the first electrode 10, and the second supporting branch 23 is near the left end of the second main body 21 and adjacent to the first electrode 10 which is in the same pair with the second electrode 20.

The first electrode 10 further defines a first flow hole 113 extending through the first main body 11 thereof. The first flow hole 113 is located between the first extension electrode 12 and the first supporting branch 13. The second electrode 20 further defines a second flow hole 213 extending through the second main body 21 thereof. The second flow hole 213 is located between the second extension electrode 22 and the second supporting branch 23.

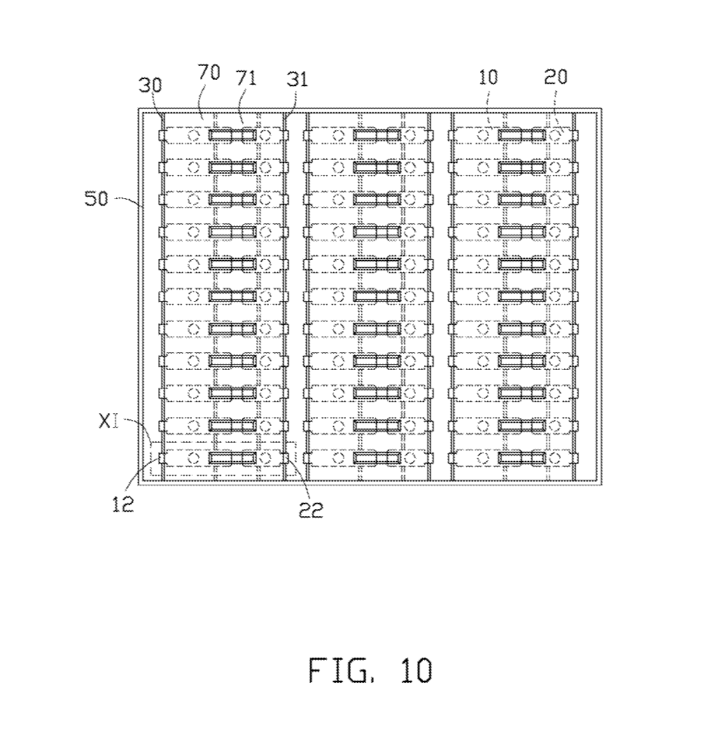

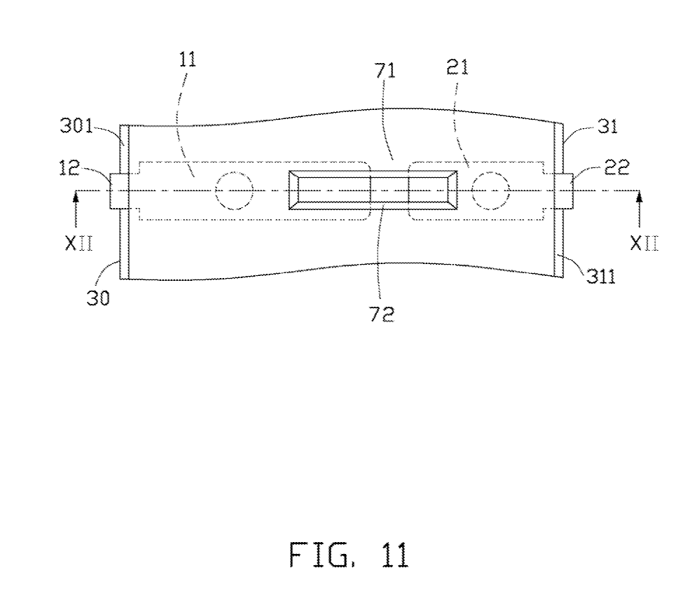

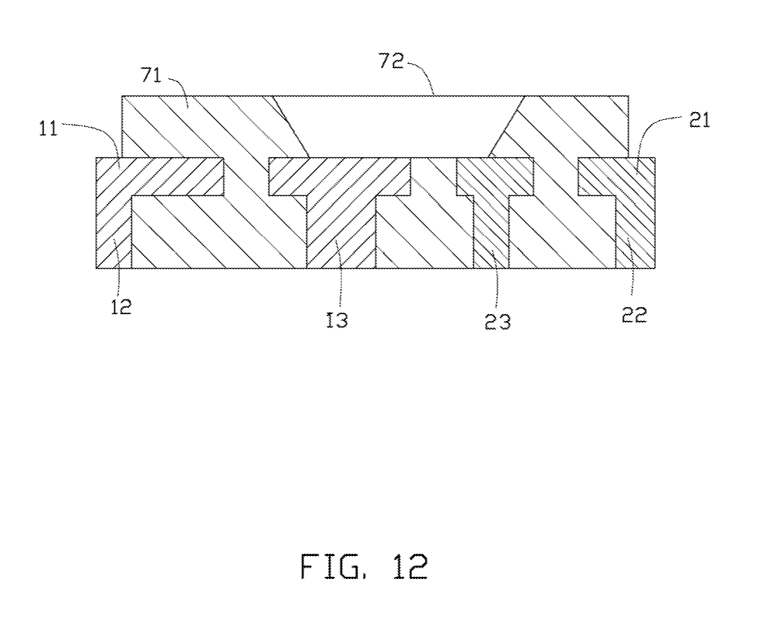

In step S102 (also referring to FIGS. 10-13), a molded base consisting of a plurality of molded bodies 70 is formed to engage with the lead frame 50. The molded bodies 70 are formed corresponding to the pairs of the first and second electrodes 10, 20, respectively. In the depicted embodiment, there are three molded bodies 70. Each molded body 70 surrounds and covers a plurality of pairs of the first and second electrodes 10, 20 disposed in two adjacent columns. Each molded body 70 forms a plurality of reflecting cups 71. Each reflecting cup 71 defines a receiving cavity 72 therein, and the receiving cavity 72 is located above a corresponding pair of the first and second electrodes 10, 20. The first and second extension electrodes 12, 22, together with the first and second tie bars 30, 31 are exposed from a periphery of the corresponding molded body 70. Bottoms of the first and second supporting branches 13, 23 are exposed at a bottom of the corresponding molded body 70 (see FIG. 12).

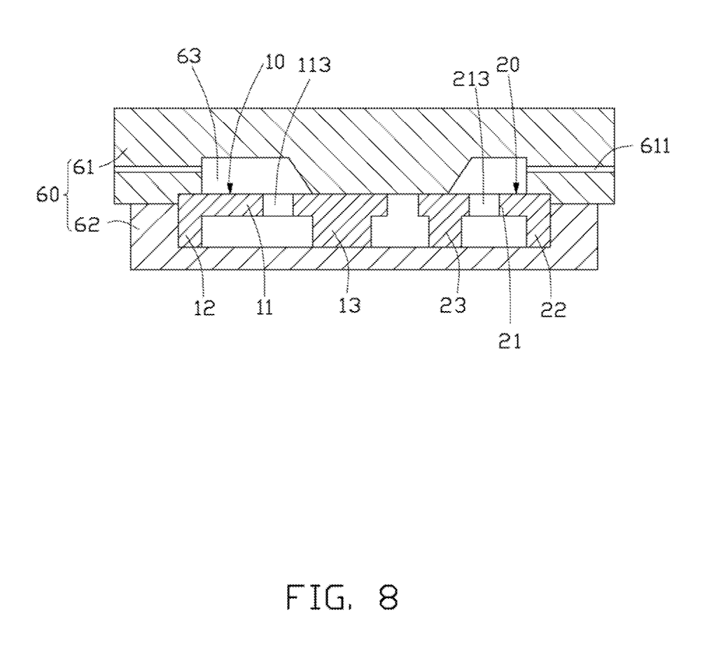

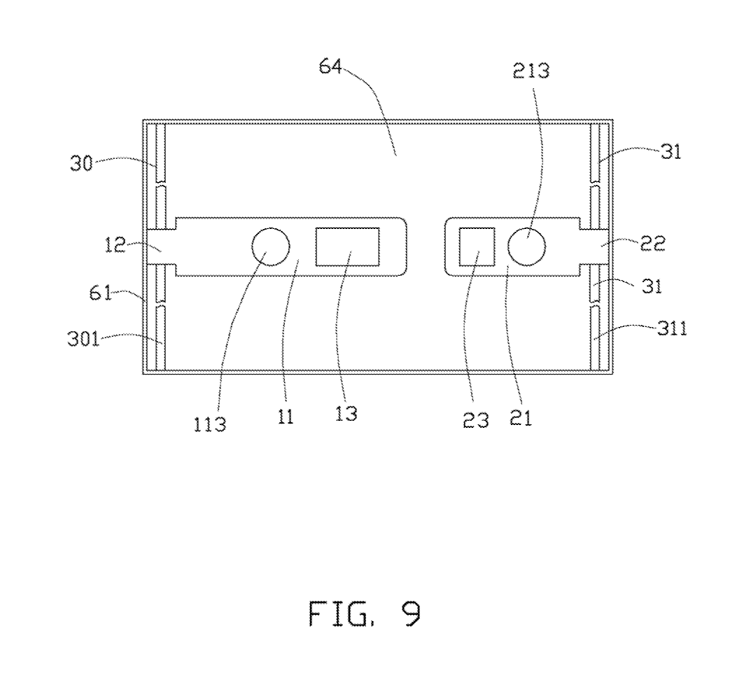

Referring to FIGS. 8-9, the molded bodies 70 are formed in a mold 60 by injection molding. The mold 60 includes a male mold 61, and a female mold 62 engaged with the male mold 61. The male and female molds 61, 62 cooperatively define a cavity 63 therein. The lead frame 50 is received in the cavity 63 of the mold 60.

Tops of the first and second extension electrodes 12, 22 of each pair of the first and second electrodes 10, 20 are covered and totally engaged by the male mold 61. The top surfaces 111, 121 of the first and second main bodies 11, 21 are covered and partially engaged by the male mold 61. A plurality of pairs of the first and second extension electrodes 12, 22 arranged in two adjacent columns, a corresponding first tie bar 30 which interconnects the first extension electrodes 12 in the same column, a corresponding second tie bar 31 which interconnects the second extension electrode 22, and two opposite sides of the lead frame 50 cooperatively define an enclosed area 64 therebetween.

The molded body 70 is made of a material selected from a group consisting of polyphthalamide (PPA) resin, epoxy molding compound, and silicone molding compound. The melted molding material is injected into the enclosed areas 64 through channels 611 formed in the male mold 61. The molding material flows around the first and second supporting branches 13, 23, and flows through the first and second flow holes 113, 213 to fill the cavity 63, thereby forming the reflecting cups 71. The plurality of reflecting cups 71 of a corresponding molded body 70 is arranged in a column. Each reflecting cup 71 is located on a corresponding pair of the first and second electrodes 10, 20 and defines a receiving cavity 72 located above the corresponding pair of the first and second electrodes 10, 20.

In step S103, the male mold 61 is separated from the female mold 62 to obtain a semi-finished product consisting of the lead frame 50, and then the first and second tie bars 30, 31 are removed from the lead frame 50 by machining or laser cutting, whereby the connections between the first extension electrodes 12 arranged in the same column and the connections between the second extension electrodes 22 arranged in the same column are broken.

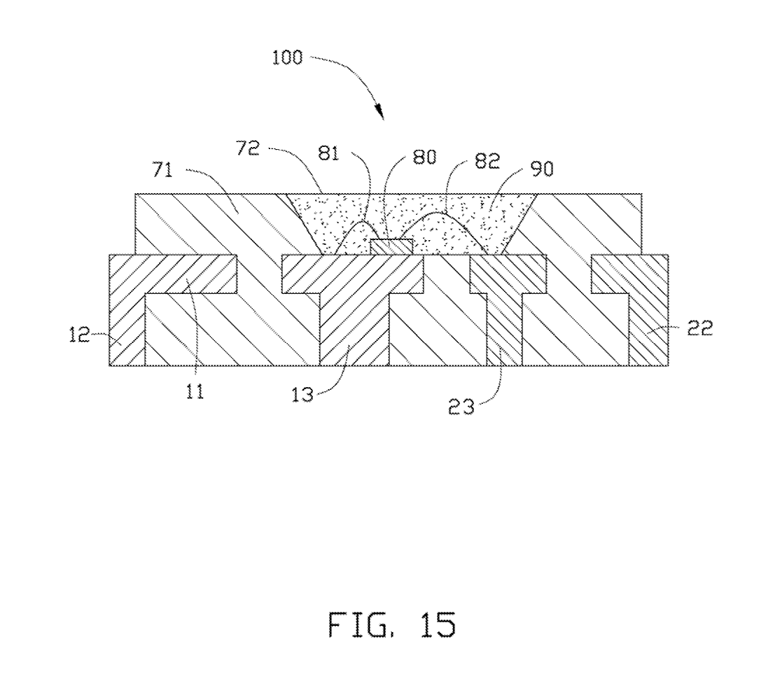

In step S104, a plurality of LED dies 80 are disposed in the corresponding receiving cavities 72, respectively. Each LED die 80 is electrically connected to the corresponding pair of the first and second electrodes 10, 20 exposed at a bottom of the corresponding receiving cavity 72 via gold wires 81, 82 (see FIGS. 14 and 15).

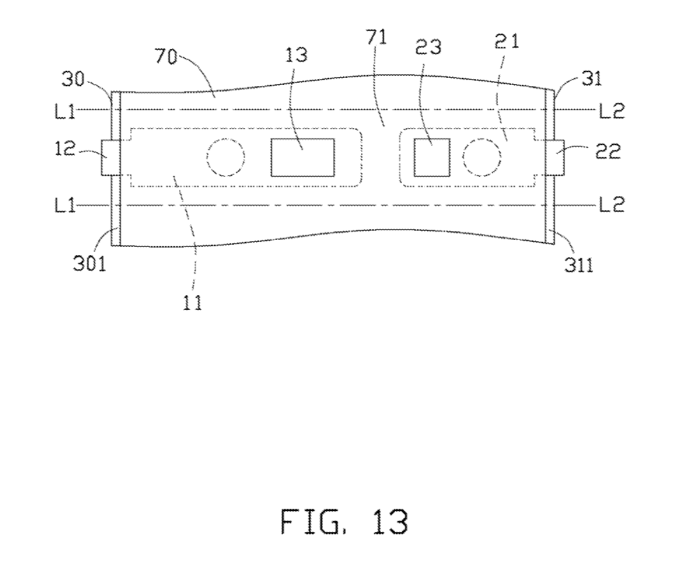

In step S105, the molded bodies 70 are separated into a plurality of individual elements by cutting along intermediate lines L₁L₂ (see FIG. 13) between every two adjacent pairs of the first and second electrodes 10, 20 firstly and then along lines perpendicular to the intermediate lines L₁L₂ to separate the pair of the first and second electrodes 10, 20 from an adjacent pair of the first and second electrodes 10. 20, whereby a plurality of individual LED packages 100 each being as shown in FIGS. 14-16 are obtained. In the present embodiment, the molded bodies 70 are separated into individual elements by mechanically cutting along the intermediate lines L₁L₂ in a transverse direction and then along lines in a longitudinal direction perpendicular to the transverse direction.

Referring to FIGS. 14-16, the LED package 100 includes a pair of the first and second electrodes 10, 20, a reflecting cup 71 surrounding the pair of the first and second electrodes 10, 20, and an LED die 80 disposed in the receiving cavity 72 of the reflecting cup 71 and electrically connected to the pair of the first and second electrodes 10, 20. The first and second extension electrodes 12, 22 are exposed out of a periphery of the corresponding reflecting cup 71. The first and second supporting branches 13, 23 are exposed at a bottom of the corresponding reflecting cup 71.

Alternatively, the LED dies 80 can be disposed in the corresponding receiving cavities 72 of the reflecting cups 71 after the molded bodies 70 are separated into a plurality of individual elements.

It is to be understood that the method for manufacturing LED packages 100 further includes a step of electroplating a metal film (not shown) covering the exposed outer surfaces of each pair of the first and second electrodes 10, 20 before the step of disposing the LED dies 80 in the corresponding receiving cavities 72. The metal film can contain silver powders so as to enhance reflectivity performance of the LED packages 100. In addition, the metal film can also prevent the LED packages 100 from oxidation to prolong the service life of the LED packages 100.

It is to be understood that the method further includes a step of forming an encapsulating layer 90 (see FIG. 15) in the receiving cavity 72 of the each reflecting cup 71 to encapsulate the LED die 80 after the LED dies 80 are disposed in the corresponding receiving cavities 72. The encapsulating layer 90 contains phosphor particles (not labeled) therein to scatter and transfer a wavelength of light emitted from the LED die 80.

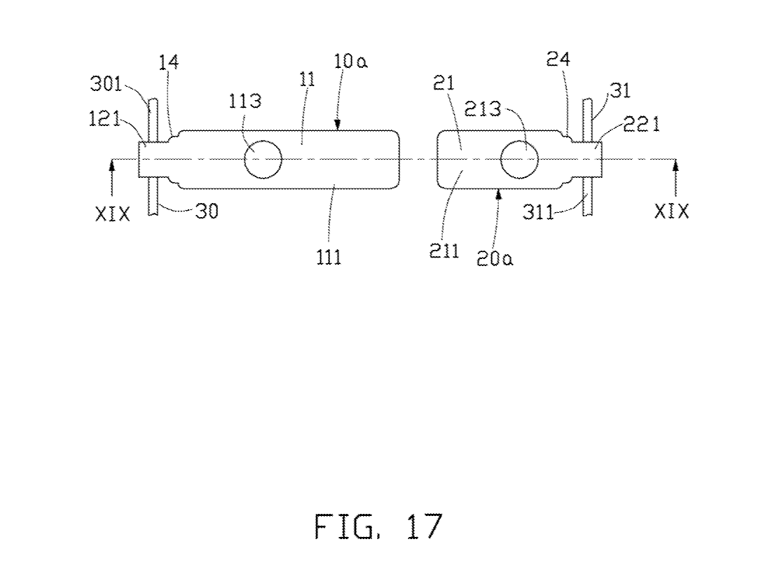

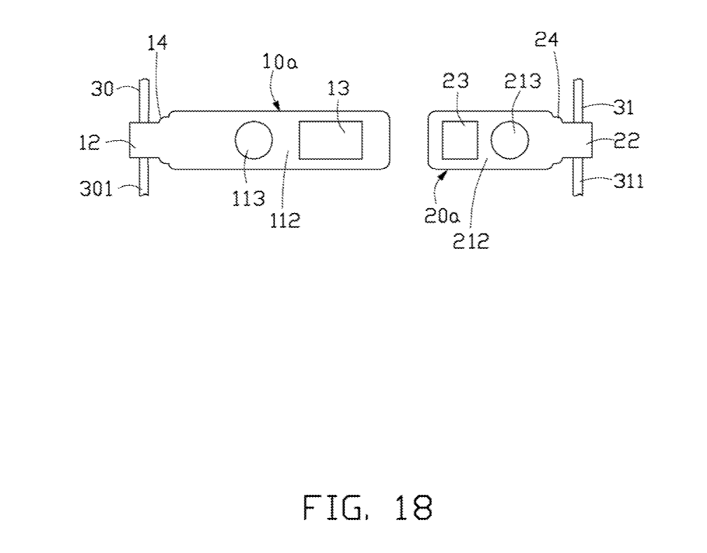

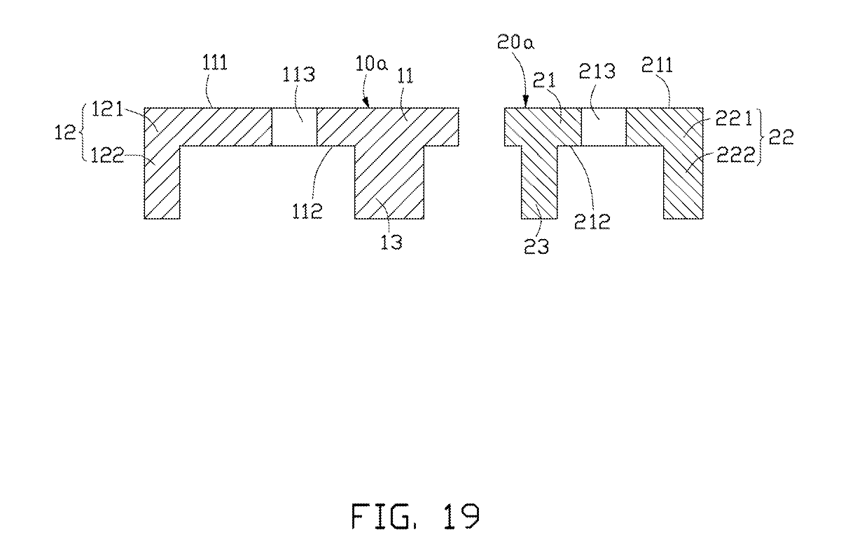

Referring to FIGS. 17-19, a pair of the first and second electrodes 10a, 20a in accordance with a second embodiment of the present disclosure is shown. Different from the first and second electrodes 10, 20 of the lead frame 50 shown in FIG. 2, the first electrode 10a in the second embodiment further includes a pair of first rounded ears 14 respectively protruding out from two opposite sides of a joint of the first extension electrode 12 and the first main body 11, and the second electrode 20a in the second embodiment further includes a pair of second rounded ears 24 respectively protruding out from two opposite sides of a joint of the second extension electrode 22 and the second main body 21.

The pair of first rounded ears 14 is integrally formed with the first extension electrode 12 and the first main body 11. The pair of second rounded ears 24 is integrally formed with the second extension electrode 22 and the second main body 21. The first and second rounded ears 14, 24 can increase an effective engaging area between the first electrode 10a and the second electrode 20a and the molded body (not shown), whereby the LED packages (not shown) using the first and second electrode 10a, 20a can have an improved mechanical strength regarding the connection between the electrodes and the corresponding molded body. The pairs of the first and second rounded ears 14, 24 are completely covered by the corresponding molded body after the step of forming a plurality of molded bodies engaging with the pairs of the first and second electrodes 10a, 20a.

In the present disclosure, the first and second main bodies 11, 21 and the first and second supporting branches 13, 23 are embedded into the corresponding reflecting cup 71, whereby the bonding strength between each pair of the first and second electrodes 10, 20 and the corresponding reflecting cup 71 is enhanced.

The LED package 100 can be electrically connected to external power source (not shown) through bottoms of the first and second supporting branches 13, 23 or the first and second extension electrodes 12, 22; thus the LED package 100 can be used as a top-view type light source or a side-view type light source according to actual requirements.

In use, heat generated from the LED die 80 is mainly conducted to the first and second electrodes 10, 20, a part of the heat absorbed by the first and second electrodes 10, 20 is dissipated to the ambient environment through bottoms of the first and second supporting branches 13, 23, and a part of the heat absorbed by the first and second electrodes 10, 20 is dissipated to the ambient environment through the first and second extension electrodes 12, 22. Thus, the LED package 100 can have a high heat-dissipating efficiency.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred.

What is claimed is:

1. A method for manufacturing LED (light emitting diode) packages comprising:
providing a lead frame, the lead frame comprising a plurality of pairs of electrodes arranged in a matrix, and a plurality of first and second tie bars, each pair of electrodes comprising a first electrode and a second electrode adjacent to the first electrode, the first electrodes being arranged in a plurality of columns, and the second electrodes being arranged in a plurality of columns, wherein each first electrode comprises an elongated first main body and a first extension electrode protruding laterally from one end of the first main body, each second electrode comprises an elongated second main body and a second extension electrode protruding laterally from one end of the second main body, the first extension electrodes arranged in the same column are connected by a corresponding first tie bar, and the second extension electrodes arranged in the same column are connected by a corresponding second tie bar;
forming a plurality of molded bodies engaging with the pairs of the first and second electrodes, each molded body surrounding and covering a plurality of pairs of the first and second electrodes disposed in two adjacent columns, and each molded body forming a plurality of reflecting cups, each reflecting cup defining a receiving cavity therein and being located over a corresponding pair of the first and second electrodes, wherein the first and second extension electrodes, together with the first and second tie bars, are exposed from an outer periphery of a corresponding molded body;
removing the first and second tie bars from the lead frame;
disposing a plurality of LED dies in the receiving cavities, respectively, each LED die being electrically connected to the corresponding pair of first and second electrodes exposed at a bottom of a corresponding receiving cavity; and
cutting the molded bodies along intermediate lines between every two adjacent pairs of the first and second electrodes in a first direction and then along a second direction perpendicular to the first direction to obtain a plurality of individual LED packages, each LED package comprising a pair of the first and second electrodes, a reflecting cup surrounding the pair of the first and second electrodes, and an LED die disposed in a receiving cavity of the reflecting cup.

2. The method for manufacturing LED packages of claim 1, wherein each first extension electrode of the first electrode is located at the end of the first main body away from a corresponding second electrode that is in same pair with the first electrode, and each second extension electrode of the second electrode is located at the end of the second main body away from a corresponding first electrode that is in same pair with the second electrode.

3. The method for manufacturing LED packages of claim 2, wherein the first and second main bodies each comprise a top surface and a bottom surface at opposite sides thereof, the first electrode further comprises a first supporting branch protruding downwardly from the bottom surface of the first main body thereof, and the second electrode further comprises a second supporting branch protruding downwardly from the bottom surface of the second main body thereof.

4. The method for manufacturing LED packages of claim 3, wherein the first and second supporting branches are embedded into the corresponding molded body, and bottoms of the first and second supporting branches are exposed at a bottom of the corresponding molded body.

5. The method for manufacturing LED packages of claim 2, wherein the first and second extension electrodes each have an inverted L-shaped configuration.

6. The method for manufacturing LED packages of claim 5, wherein each first extension electrode comprises a first connecting portion extending horizontally and outwardly from the corresponding first main body and a first extension portion extending downwardly from the distal end of the first connecting portion, and each second extension electrode comprises a second connecting portion extending horizontally and outwardly from the corresponding second main body and a second extension portion extending downwardly from the distal end of the second connecting portion.

7. The method for manufacturing LED packages of claim 6, wherein tops of the first and second extension electrodes are respectively coplanar with tops of the corresponding first and second main bodies, and bottoms of the first and second extension electrodes are coplanar with a bottom of the corresponding molded body.

8. The method for manufacturing LED packages of claim 2, wherein the first tie bar comprises a plurality of spaced first connecting sections each interconnecting two adjacent first extension electrodes arranged in the same column, and the second tie bar comprises a plurality of spaced second connecting sections each interconnecting two adjacent second extension electrodes arranged in the same column.

9. The method for manufacturing LED packages of claim 8, wherein a height of each first connecting section of the first tie bar is equal to that of the corresponding first extension electrodes, and a height of each second connecting section of the second tie bar is equal to that of the corresponding second extension electrodes.

10. The method for manufacturing LED packages of claim 9, wherein each first connecting section of the first tie bar is spaced from the corresponding first main body, and each second connecting section of the second tie bar is spaced from the corresponding second main body.

11. The method for manufacturing LED packages of claim 2, wherein each first electrode further comprises a pair of first rounded ears respectively protruding out from two opposite sides of a joint of the first extension electrode and the first main body, each second electrode comprises a pair of second rounded ears respectively protruding out from two opposite sides of a joint of the second extension electrode and the second main body, and the pairs of the first and second rounded ears are completely covered by the corresponding molded body.

12. The method for manufacturing LED packages of claim 2, wherein each first electrode further comprises a first flow hole extending through the first main body thereof, and each second electrode further comprises a second flow hole extending through the second main body thereof, and the first and second flow holes are completely filled by the corresponding molded body.

13. The method for manufacturing LED packages of claim 2, further comprising a step of forming an encapsulating layer in the receiving cavity of each reflecting cup to encapsulate the LED die therein after the step of disposing the LED dies in the corresponding receiving cavities.

14. The method for manufacturing LED packages of claim 13, wherein the encapsulating layer contains phosphor particles therein.

15. The method for manufacturing LED packages of claim 2, wherein the molded body is formed in a mold by injection molding, the mold comprising a male mold and a female mold engaged with the male mold, and the male mold and the female mold cooperatively defining a cavity to receive the lead frame therein.

16. The method for manufacturing LED packages of claim 15, wherein tops of the first and second electrodes are covered and partially engaged by the male mold, and the molding material flows in a plurality of enclosed areas, each enclosed area being cooperatively defined by a plurality of pairs of the first and second extension electrodes arranged in two adjacent columns, a corresponding first tie bar that interconnects the first extension electrodes, a corresponding second tie bar that interconnects the second extension electrodes, and two opposite sides of the lead frame.

17. The method for manufacturing LED packages of claim 2, further comprising a step of electroplating a metal film covering the exposed outer surfaces of each pair of the first and second electrodes before the step of disposing the LED dies in the corresponding receiving cavities.

18. The method for manufacturing LED packages of claim 17, wherein the metal film contains silver powders.
